(19) United States
(12) Patent Application Publication
(10) Pub. No.: US 2025/0079414 A1
(43) Pub. Date: Mar. 6, 2025

(54) ELECTRONIC PACKAGE MODULE AND METHOD FOR FABRICATION OF THE SAME

(71) Applicant: Universal Global Technology (Kunshan) Co., Ltd., Jiangsu Province (CN)

(72) Inventors: KUO-HSIEN LIAO, Jiangsu Province (CN); LI-CHENG SHEN, Jiangsu Province (CN); HUNG-YI TSAI, Jiangsu Province (CN); CHAO-HSUAN WANG, Jiangsu Province (CN); CHUN-MING CHEN, Jiangsu Province (CN); TAI-LIN WU, Jiangsu Province (CN); CHIH-SHIEN CHEN, Jiangsu Province (CN); PING-CHI HUNG, Jiangsu Province (CN)

(21) Appl. No.: 18/413,066

(22) Filed: Jan. 16, 2024

(30) Foreign Application Priority Data
Aug. 31, 2023 (CN) 202311112566.9

(51) Int. Cl. H01L 25/16; H01L 23/00

(52) U.S. Cl. CPC H01L 25/16; H01L 24/27; H01L 24/29; H01L 24/32; H01L 24/40; H01L 24/73; H01L 24/83; H01L 24/84; H01L 2224/2731; H01L 2224/29111; H01L 2224/29139; H01L 2224/29147; H01L 2224/2919; H01L 2224/32225; H01L 2224/32265; H01L 2224/40225; H01L 2224/40265; H01L 2224/404; H01L 2224/73263; H01L 2224/83005; H01L 2224/83801; H01L 2224/83862; H01L 2224/84005; H01L 2224/84862; H01L 2924/19103; H01L 2924/19104; H01L 2924/19105; H01L 2924/37001

(57) ABSTRACT

An electronic package module and a method for fabrication of the same are provided. The method includes providing an electronic component assembly and a circuit substrate. The electronic component assembly includes two electronic components and a conductive structure. The electronic components are connected to each other through a conductive adhesive material, while the electronic components are connected to the conductive structure through another conductive adhesive material. A soldering material is formed on the circuit substrate, and the electronic component assembly is disposed on the soldering material. The melting points of the conductive adhesive materials are higher than the melting point of the soldering material. As a result, the conductive adhesive materials are prevented from failure during the soldering process, and thus the process yield is improved.

### RELATED APPLICATIONS

This application claims priority to China Application Serial Number 202311112566.9, filed Aug. 31, 2023, which is herein incorporated by reference in its entirety.

### BACKGROUND

### Technical Field

The present disclosure relates to an electronic package module. More particular, the present disclosure relates to the electronic package module with 3D integrated circuit structure and the method for fabrication of the same.

### Description of Related Art

Electronic package modules with 3D integrated circuit structure contain various types of active components and passive components. In general, components are adhered to each other and disposed on a circuit substrate through soldering materials. Considering that the distribution of electronic components and the internal structure of package modules, different soldering processes must be applied to connect different regions of an electronic package module during the packaging process. For example, two electronic components are primarily connected by a first soldering process, and then these two electronic components are connected to a circuit substrate by a second soldering process.

However, the adhered soldering material is prone to be affected and melted by the temperature during follow-up soldering process. The molten soldering material will cause the electronic components to be deviated or even to be detached. Thus, the electrical connections between the electronic components are blocked, so that the electronic package module is failed.

### SUMMARY

Accordingly, the disclosure is to provide an electronic package module and the method for fabrication of the same, thereby increasing the yield rate of the electronic package module.

At least one embodiment of the disclosure provides a method for fabricating an electronic package module including providing an electronic component assembly including a first electronic component, a second electronic component, a conductive structure and two conductive adhesive materials. The first electronic component is connected to the second electronic component through one of the conductive adhesive materials, and the second electronic component is connected to the conductive structure through the other one of the conductive adhesive materials. A circuit substrate is provided. A soldering material is formed on the circuit substrate, and the melting point of the conductive adhesive materials is higher than the melting point of the soldering material. The electronic component assembly is disposed on the soldering material after the soldering material is formed. The soldering material is located between the first electronic component and the circuit substrate, and the electronic component assembly is electrically connected to the circuit substrate through the soldering material.

At least one embodiment of the disclosure provides a method for fabricating an electronic package module including providing an electronic component assembly including a first electronic component, a second electronic component, a conductive structure and three conductive adhesive materials. The first electronic component is connected to the second electronic component through one of the conductive adhesive materials, and the second electronic component is connected to the conductive structure through another one of the conductive adhesive materials. The first electronic component is connected to the conductive structure through the other one of the conductive adhesive materials. A circuit substrate is provided. A soldering material is formed on the circuit substrate, and the melting point of at least two of the conductive adhesive materials is higher than the melting point of the soldering material. The electronic component assembly is disposed on the soldering material after the soldering material is formed. The soldering material is located between the first electronic component and the circuit substrate, and the electronic component assembly is electrically connected to the circuit substrate through the soldering material.

At least one embodiment of the disclosure provides an electronic package module. The electronic package module includes a circuit substrate, a first electronic component, a second electronic component and a conductive structure. The first electronic component is disposed on the circuit substrate. The second electronic component is disposed on the first electronic component, while the first electronic component is located between the circuit substrate and the second electronic component. The conductive structure is disposed on the second electronic component and connected to the second electronic component and the circuit substrate. The electronic package module further includes two conductive adhesive materials and a soldering material. One of the conductive adhesive materials is located between the first electronic component and the second electronic component, and the other one of the conductive adhesive materials is located between the second electronic component and the conductive structure. The second electronic component is electrically connected to the first electronic component through the one of the conductive adhesive materials and is electrically connected to the conductive structure through the other one of the conductive adhesive materials. The soldering material is located between the circuit substrate and the first electronic component. The circuit substrate is electrically connected to the first electronic component through the soldering material, and the melting point of the conductive adhesive materials is higher than the melting point of the soldering material.

At least one embodiment of the disclosure provides an electronic package module. The electronic package module includes a circuit substrate, a first electronic component, a second electronic component and a conductive structure. The first electronic component is disposed on the circuit substrate, while the second electronic component is disposed on the first electronic component. The first electronic component is located between the circuit substrate and the second electronic component. The conductive structure is disposed on the second electronic component and the first electronic component. The conductive structure is connected to the second electronic component and the circuit substrate and is connected to the second electronic component and the first electronic component. The electronic package module further includes three conductive adhesive materials and a soldering material. One of the conductive adhesive materials is located between the first electronic component and the second electronic component, and another one of the conductive adhesive materials is located between the second electronic component and the conductive structure. The other one of the conductive adhesive materials is located between the first electronic component and the conductive structure. The first electronic component is electrically connected to the conductive structure through the one of the conductive adhesive materials. The second electronic component is electrically connected to the first electronic component and the conductive structure separately through the other two of the conductive adhesive materials. The soldering material is located between the circuit substrate and the first electronic component. The circuit substrate is electrically connected to the first electronic component through the soldering material, and the melting point of at least two of the conductive adhesive materials is higher than the melting point of the soldering material.

According to the aforementioned embodiments, the soldering material and the high temperature resistant conductive adhesives are separately applied in different adhering processes. Since the melting point of the soldering material and the melting point of the high temperature resistant conductive adhesives are different, the high temperature during the soldering process is not able to break the connection of the conductive adhesives. Therefore, the detachment or the electrical failure of electronic components are reduced, and thereby improving the yield rate of packaging process.

### BRIEF DESCRIPTION OF THE DRAWINGS

To illustrate more clearly the aforementioned and the other features, merits, and embodiments of the present disclosure, the description of the accompanying figures are as follows:

FIG. 1A to FIG. 1D illustrate cross-sectional views of a method for fabricating an electronic package module in accordance with one embodiment of the present disclosure.

FIG. 2 illustrates a cross-sectional view of a method for fabricating an electronic package module in accordance with another embodiment of the present disclosure.

FIG. 3 illustrates a cross-sectional view of an electronic package in accordance with one embodiment of the present disclosure.

FIG. 4 illustrates a cross-sectional view of an electronic package in accordance with another embodiment of the present disclosure.

### DETAILED DESCRIPTION

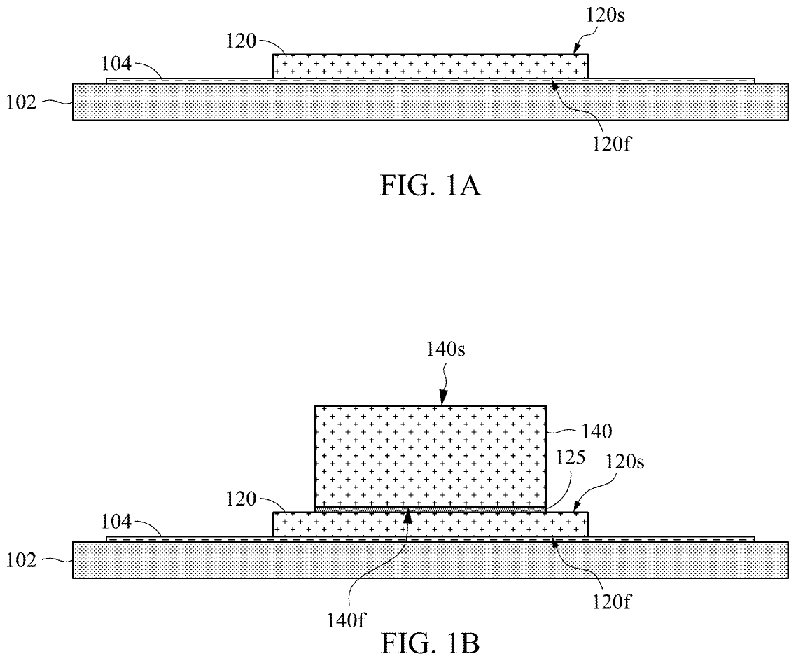

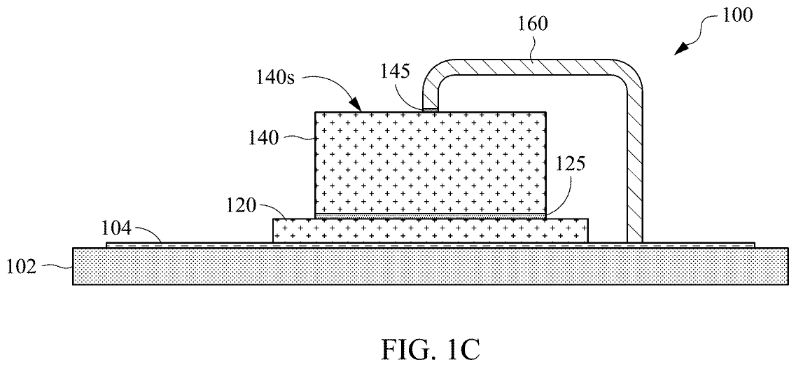

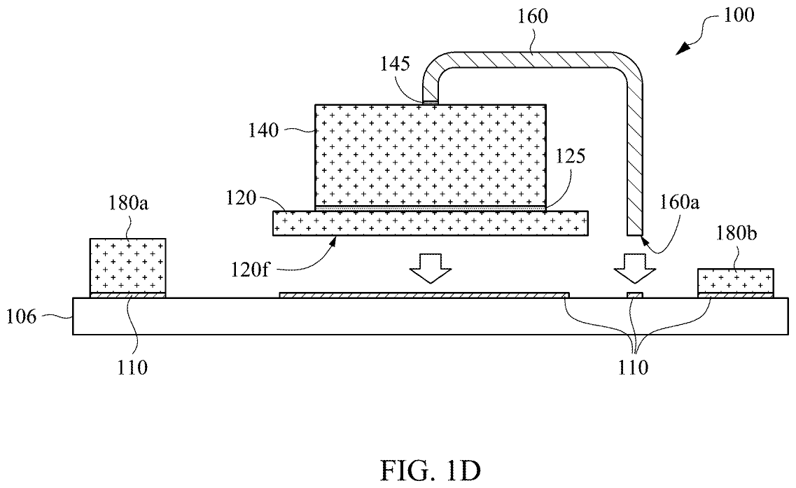

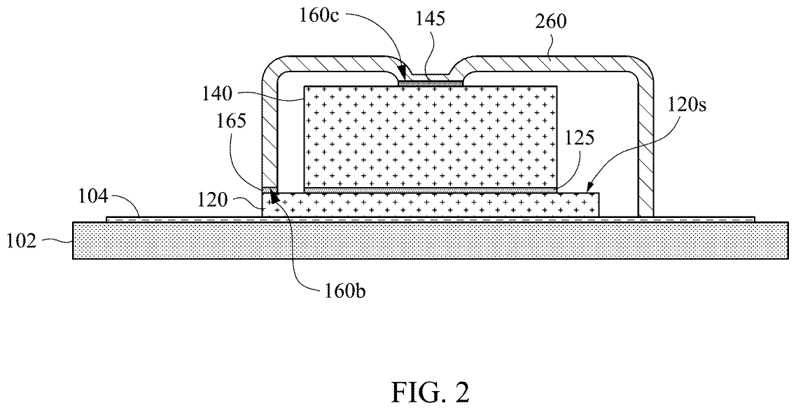

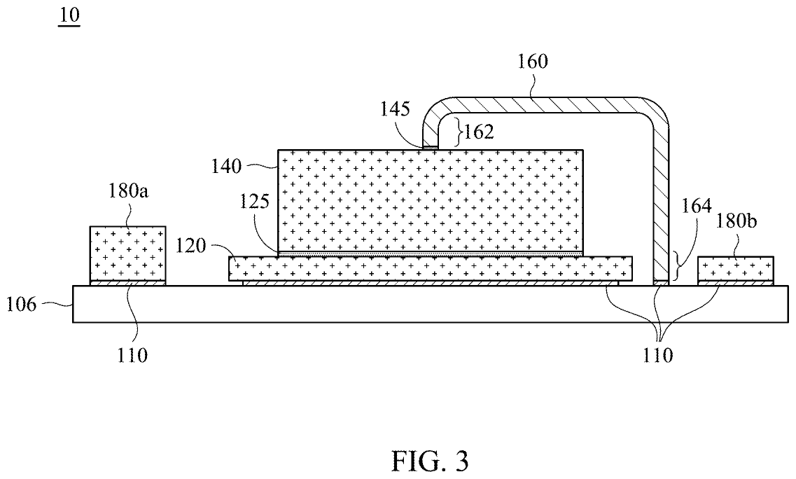

A method for fabrication of the electronic package module is disclosed while FIG. 1A to FIG. 1D and FIG. 2 illustrate sequent steps of this method in accordance with at least one embodiment of present disclosure. Referring to FIG. 1A to FIG. 1C, firstly, an electronic component assembly 100 including the first electronic component 120, the second electronic component 140, the conductive structure 160, the conductive adhesive material 125 and the conductive adhesive material 145 is provided. The detailed steps of providing the electronic component assembly 100 includes providing the carrier 102 and disposing the first electronic component 120 on the carrier 102 as shown in FIG. 1A.

In some embodiments of the disclosure, the fixture 104 is disposed on the carrier 102, and the first electronic component 120 is disposed on the fixture 104. For example, the fixture 104 may be a double sided tape in this embodiment. One side of the double sided tape is adhered to the carrier 102, while the first electronic component 120 is adhered to the other side of the double sided tape. The first electronic component 120 includes the surface 120f and the surface 120s, while the surface 120f and the surface 120s are located on two opposite sides of the first electronic component 120. The first electronic component 120 is adhered to the fixture 104 as the surface 120f faces to the carrier 102.

Afterwards, referring to FIG. 1B, the conductive adhesive material 125 is disposed on the first electronic component 120, and the second electronic component 140 is adhered to the conductive adhesive material 125. The conductive adhesive material 125 is disposed on the surface 120s of the first electronic component 120, and the conductive adhesive material 125 is located between the first electronic component 120 and the second electronic component 140. As shown in FIG. 1B, the second electronic component 140 has the surface 140f and the surface 140s. The second electronic component 140 is adhered to the conductive adhesive material 125 as the surface 140f faces to the first electronic component 120.

It is worth mentioning, the first electronic component 120 may be an active component such as a transistor, while the second electronic component 140 may be a passive component such as an inductor or a capacitor in the embodiment. However, the categories of the first electronic component 120 and the second electronic component 140 are not limited to this embodiment. That is, the first electronic component 120 may be a passive component, while the second electronic component 140 may be an active component in other embodiments of the present disclosure.

Referring to FIG. 1C, the conductive adhesive material 145 is adhered to the second electronic component 140, and the conductive structure 160 is adhered to the conductive adhesive material 145. In the embodiment, the conductive adhesive material 145 is disposed on the surface 140s of the second electronic component 140, and the conductive adhesive material 145 is located between the second electronic component 140 and the conductive structure 160. However, the conductive adhesive material 145 is not limited to be disposed on the aforementioned position. In other embodiments, the conductive adhesive material 145 may be disposed on another surface (e.g. the side surface of the second electronic component 140 in FIG. 1C) of the second electronic component 140.

On the other hand, the first electronic component 120 is connected to the second electronic component 140 through the conductive adhesive material 125, while the second electronic component 140 is connected to the conductive structure 160 through the conductive adhesive material 145. Furthermore, the conductive adhesive material 125 may be electrically connected to the first electronic component 120 and the second electronic component 140, while the conductive adhesive material 145 may be electrically connected to the second electronic component 140 and the conductive structure 160.

It is worth mentioning, the conductive adhesive material 125 and the conductive adhesive material 145 may include adhesive materials with conductivity, such as the conductive adhesive, solder paste or similarity thereof. For instance, the conductive adhesive material 125 and the conductive adhesive material 145 may be the conductive adhesive including copper (or silver) and resin. Thus, curing of the conductive adhesive material 125 and the conductive adhesive material 145 may be accomplished by heating the electronic component assembly 100 after the conductive structure 160 is disposed on the conductive adhesive material 145.

Referring to FIG. 1D, the carrier 102 (denoted in FIG. 1C) is removed after the conductive structure 160 is adhered to the conductive adhesive material 145, and the surface 120f of the first electronic component 120 is exposed. Moreover, the circuit substrate 106 is provided, and the soldering material 110 is formed on the circuit substrate 106. After the soldering material 110 is formed, the electronic component assembly 100 is disposed on the soldering material 110. The soldering material 110 is located between the first electronic component 120 and the circuit substrate 106, while the surface 120f of the first electronic component 120 faces to the circuit substrate 106 and is disposed on the soldering material 110.

On the other hand, the third electronic component 180a and the third electronic component 180b are disposed on the soldering material 110 after the soldering material 110 is formed, while the soldering material 110 is located between the circuit substrate 106 and the third electronic component 180a (and the third electronic component 180b). Although the third electronic component 180a and the third electronic component 180b are disposed on the circuit substrate 106 before the electronic component assembly 100 is disposed on the soldering material 110, the disclosure is not limited to the embodiment. In other embodiments, the third electronic component 180a and the third electronic component 180b may be disposed on the circuit substrate 106 after the electronic component assembly 100 is disposed on the soldering material 110.

Specifically, referring to FIG. 1C and FIG. 1D, the end surface 160a of the conductive structure 160 and the surface 120f of the first electronic component 120 are both adhered to the same side of the fixture 104. Thus, the end surface 160a of the conductive structure 160 is exposed after the carrier 102 is removed, while the surface 120f of the first electronic component 120 is flush with the end surface 160a of the conductive structure 160. The electronic component assembly 100 is electrically connected to the circuit substrate 106 through the soldering material 110. In addition, the soldering material 110 may be located between the conductive structure 160 and the circuit substrate 106, while the end surface 160a of the conductive structure 160 may be connected to the circuit substrate 106 through the soldering material 110.

The soldering material 110 may include the soldering materials, such as tin solder, copper solder or silver solder, and the soldering material 110 may be disposed on the circuit substrate 106 through printing or dispensing. For example, the soldering material 110 may be high temperature solder whose melting point ranges from 240° C. to 280° C., while the conductive adhesive material 125 and the conductive adhesive material 145 may be conductive adhesive (e.g. silver conductive adhesive or copper conductive adhesive) whose melting point is higher than 280° C. As a result, while the electronic component assembly 100 is disposed on the soldering material 110 through soldering, the conductive adhesive material 125 and the conductive adhesive material 145 are not melted under the temperature of soldering.

FIG. 2 illustrates a part of steps according with another embodiment of the disclosure, and this embodiment is similar to aforementioned embodiment. Specifically, the embodiment includes the steps illustrated from FIG. 1A to FIG. 1C. However, the electronic component assembly 100 of this embodiment further includes the conductive adhesive material 165, so that the step of providing the electronic component assembly 100 further includes disposing the conductive adhesive material 165 on the first electronic component 120. The conductive adhesive material 165 is located between the first electronic component 120 and the conductive structure 260, and the first electronic component 120 is connected to the conductive structure 260 through the conductive adhesive material 165. In various embodiments of the disclosure, the conductive adhesive material 125, conductive adhesive material 145 and the conductive adhesive material 165 may be disposed through printing or dispensing.

The conductive structure 260 may be connected to the circuit substrate 106 and the second electronic component 140 after the electronic component assembly 100 is disposed on the soldering material 110, even though this step is not illustrated in figures. In addition, the conductive structure 260 may be connected to the first electronic component 120 and the second electronic component 140. Specifically, the end surface 160b and the end surface 160c are connected to the first electronic component 120 and the second electronic component 140 separately through the conductive adhesive material 165 and the conductive adhesive material 145.

It is worth mentioning, at least two of the conductive adhesive material 125, the conductive adhesive material 145 and the conductive adhesive material 165 have melting points which are higher than the melting point of the soldering material 110. For example, in this embodiment, the soldering material 110 may be a high temperature solder whose melting point ranges from 240° C. to 280° C., while at least two of the conductive adhesive material 125, the conductive adhesive material 145 and conductive adhesive material 165 may be conductive adhesives (e.g. silver conductive adhesive or copper conductive adhesive) whose melting points are higher than 280° C. Specifically, a better embodiment of the disclosure is that the conductive adhesive material 125 and the conductive adhesive material 165 may be conductive adhesives whose melting points are higher than 280° C., while the conductive adhesive material 145 may be a high temperature solder whose melting point ranges from 240° C. to 280° C.

However, the disclosure is not limited to the embodiment. In other embodiments, the conductive adhesive material 125 and the conductive adhesive material 145 may be conductive adhesives whose melting points are higher than 280° C., while the conductive adhesive material 165 and the soldering material 110 may be high temperature solders whose melting points range from 240° C. to 280° C. Furthermore, the conductive adhesive material 165 and the soldering material 110 may include the same materials. In addition, all of the conductive adhesive material 125, the conductive adhesive material 145 and the conductive adhesive material 165 may be conductive adhesives whose melting points are higher than 280° C.

By the method of fabricating the electronic package module illustrated in FIG. 1A to FIG. 1D, the electronic package module 10 shown in FIG. 3 may be accomplished. The electronic package module 10 includes the circuit substrate 106, the first electronic component 120, the second electronic component 140 and the conductive structure 160. The first electronic component 120 is disposed on the circuit substrate 106, and the second electronic component 140 is disposed on the first electronic component 120. In the embodiment, the first electronic component 120 is located between the circuit substrate 106 and the second electronic component 140.

The electronic package module 10 includes the conductive adhesive material 125 which is located between the first electronic component 120 and the second electronic component 140. The conductive adhesive material 125 may include adhesive materials with conductivity (e.g. the conductive adhesive or solder paste), so that the second electronic component 140 is electrically connected to the first electronic component 120 through the conductive adhesive material 125.

The conductive structure 160 is disposed on the second electronic component 140 and is connected to the second electronic component 140 and the circuit substrate 106. On the other hand, the electronic package module electronic package module 10 includes the conductive adhesive material 145 which is located between the second electronic component 140 and the conductive structure 160. The conductive adhesive material 145 may include adhesive materials with conductivity (e.g. the conductive adhesive or solder paste), so that the second electronic component 140 is electrically connected to the conductive structure 160 through the conductive adhesive material 145.

The electronic package module 10 further includes the soldering material 110 which is located between the circuit substrate 106 and the first electronic component 120. The circuit substrate 106 is electrically connected to the first electronic component 120 through the soldering material 110. Moreover, the circuit substrate 106 is electrically connected to the conductive structure 160 through the soldering material 110. Specifically, the conductive structure 160 includes the end part 162 and the end part 164 as shown in FIG. 3. The end part 162 is connected to the second electronic component 140 through the conductive adhesive material 145, while the end part 164 is connected to the circuit substrate 106 through the soldering material 110. In addition, the circuit substrate 106 may further include at least one layer of solder mask (not shown) which may cover the surface of the circuit substrate 106 and expose the soldering material 110.

It is worth mentioning, the electronic package module 10 further includes the third electronic component 180a and the third electronic component 180b in the embodiment. The third electronic component 180a and the third electronic component 180b are located on and are electrically connected to the circuit substrate 106 through the soldering material 110. In various embodiments of the disclosure, the third electronic component 180a and the third electronic component 180b may be passive components, such as inductors or capacitors, or may be active components, such as transistors.

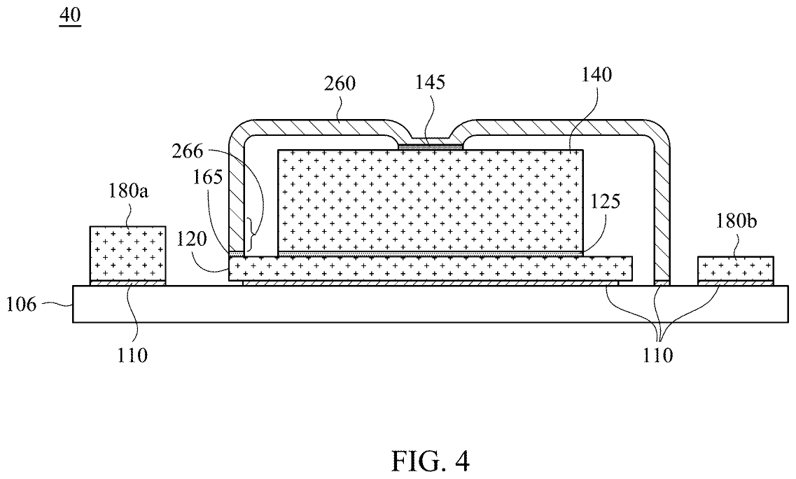

On the other hand, the electronic package module 40 shown in FIG. 4 may be accomplished by the method of fabricating the electronic package module illustrated in FIG. 2. The electronic package module 40 is similar to the electronic package module 10, while the difference between these two is that the electronic package module 40 further includes the conductive adhesive material 165. The conductive adhesive material 165 is located between the first electronic component 120 and the conductive structure 260, and the conductive structure 260 is connected to the first electronic component 120 and the second electronic component 140. Specifically, referring to FIG. 4, the conductive structure 260 further includes the end part 266 which is electrically connected to the first electronic component 120 through the conductive adhesive material 165 in this embodiment.

In the embodiment, at least two of the conductive adhesive material 125, the conductive adhesive material 145 and the conductive adhesive material 165 may have melting points which are higher than the melting point of the soldering material 110. For example, the conductive adhesive material 125 and the conductive adhesive material 145 may be conductive adhesives whose melting points are higher than the melting point of the soldering material 110, while the melting point of the conductive adhesive material 165 may be the same as the melting point of the soldering material 110. However, the disclosure is not limited to the embodiment. In other embodiment, all of the conductive adhesive material 125, the conductive adhesive material 145 and the conductive adhesive material 165 may have melting points which are higher than the melting point of the soldering material 110.

It is worth mentioning, the quantities of the first electronic component 120, the second electronic component 140 and the conductive structure 160 (and the conductive structure 260) of the disclosure is not limited to the embodiment. In other words, the quantities of the first electronic component 120, the second electronic component 140 and the conductive structure 160 (and the conductive structure 260) may be one or above. For instance, in some embodiments, two first electronic components 120 may be disposed on the circuit substrate 106, while one second electronic component 140 and one conductive structure 160 are disposed on each of the first electronic components 120. Moreover, in some other embodiments, one first electronic component 120 is disposed on the circuit substrate 106, while two second electronic components 140 and two conductive structures 160 are disposed on the first electronic component 120.

In conclusion, the components (i.e. the first electronic component 120, the second electronic component 140 and the conductive structure 160) of the electronic component assembly are connected to each other through the conductive adhesive materials, and the melting point of at least one of the conductive adhesive materials is higher than the melting point of the soldering material. Thus, the temperature of soldering process is not high enough for the conductive adhesive materials to be melted during the soldering process of disposing the electronic components on the circuit substrate, even though the temperature reaches to the melting temperature of the soldering material. As a result, the conductive adhesive materials are prevented from being melted, so that the connections between each components of the electronic component assembly are not affected under high temperature. Further, the adhesive materials with different heat resistance (e.g. the soldering material and the conductive adhesive) is applied in different processes of the disclosure, so that the components which have been adhered in earlier processes are not detached due to higher temperature under the follow-up processes, and thereby improving the yield rate of packaging process.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A method for fabricating an electronic package module, comprising:
providing an electronic component assembly including a first electronic component, a second electronic component, a conductive structure and two conductive adhesive materials, wherein the first electronic component is connected to the second electronic component through one of the conductive adhesive materials, and the second electronic component is connected to the conductive structure through the other one of the conductive adhesive materials;
providing a circuit substrate;
forming a soldering material on the circuit substrate, wherein the melting point of the conductive adhesive materials is higher than the melting point of the soldering material; and
disposing the electronic component assembly on the soldering material after the soldering material is formed, wherein the soldering material is located between the first electronic component and the circuit substrate, and the electronic component assembly is electrically connected to the circuit substrate through the soldering material.

2. The method of claim 1, wherein providing the electronic component assembly comprising:
providing a carrier;
disposing the first electronic component on the carrier;
disposing one of the conductive adhesive materials on the first electronic component;
adhering the second electronic component to the one of the conductive adhesive materials, wherein the one of the conductive adhesive materials is located between the first electronic component and the second electronic component;
disposing the other one of the conductive adhesive materials on the second electronic component;
adhering the conductive structure to the other one of the conductive adhesive materials, wherein the other one of the conductive adhesive materials is located between the second electronic component and the conductive structure; and
removing the carrier after the conductive structure is adhered to the other one of the conductive adhesive materials, and a surface of the first electronic component is exposed, wherein the surface faces to the circuit substrate and is disposed on the soldering material.

3. The method of claim 2, wherein the surface is flush with an end surface of the conductive structure, and the end surface is connected to the circuit substrate through the soldering material.

4. The method of claim 2, further comprising:
heating the electronic component assembly to cure the conductive adhesive materials after the conductive structure is adhered to the other one of the conductive adhesive materials.

5. A method for fabricating an electronic package module, comprising:
providing an electronic component assembly including a first electronic component, a second electronic component, a conductive structure and three conductive adhesive materials, wherein the first electronic component is connected to the second electronic component through one of the conductive adhesive materials, and the second electronic component is connected to the conductive structure through another one of the conductive adhesive materials, and the first electronic component is connected to the conductive structure through the other one of the conductive adhesive materials;
providing a circuit substrate;
forming a soldering material on the circuit substrate, wherein the melting point of at least two of the conductive adhesive materials is higher than the melting point of the soldering material; and
disposing the electronic component assembly on the soldering material after the soldering material is formed, wherein the soldering material is located between the first electronic component and the circuit substrate, and the electronic component assembly is electrically connected to the circuit substrate through the soldering material.

6. The method of claim 5, wherein providing the electronic component assembly comprising:
providing a carrier;
disposing the first electronic component on the carrier;
disposing one of the conductive adhesive materials on the first electronic component;
adhering the second electronic component to the one of the conductive adhesive materials, and the one of the conductive adhesive materials is located between the first electronic component and the second electronic component;
disposing the other two of the conductive adhesive materials on the second electronic component and the first electronic component separately;
adhering the conductive structure to the other two of the conductive adhesive materials, and the other two of the conductive adhesive materials are separately located between the conductive structure and the first electronic component and between the conductive structure and the second electronic component; and
removing the carrier after the conductive structure is adhered to the other two of the conductive adhesive materials, and a surface of the first electronic component is exposed, wherein the surface faces to the circuit substrate and is disposed on the soldering material.

7. The method of claim 5, wherein the melting point of the one of the conductive adhesive materials located between the first electronic component and the second electronic component is higher than the melting point of the soldering material, and the melting point of the other one of the conductive adhesive materials located between the first electronic component and the conductive structure is higher than the melting point of the soldering material.

8. An electronic package module, comprising:
a circuit substrate;
a first electronic component disposed on the circuit substrate;
a second electronic component disposed on the first electronic component, wherein the first electronic component is located between the circuit substrate and the second electronic component;
a conductive structure disposed on the second electronic component and connected to the second electronic component and the circuit substrate;
two conductive adhesive materials, and one of the conductive adhesive materials is located between the first electronic component and the second electronic component, and the other one of the conductive adhesive materials is located between the second electronic component and the conductive structure, wherein the second electronic component is electrically connected to the first electronic component through the one of the conductive adhesive materials and is electrically connected to the conductive structure through the other one of the conductive adhesive materials; and
a soldering material located between the circuit substrate and the first electronic component, wherein the circuit substrate is electrically connected to the first electronic component through the soldering material, and the melting point of the conductive adhesive materials is higher than the melting point of the soldering material.

9. An electronic package module, comprising:
a circuit substrate;
a first electronic component disposed on the circuit substrate;
a second electronic component disposed on the first electronic component, wherein the first electronic component is located between the circuit substrate and the second electronic component;
a conductive structure disposed on the second electronic component and the first electronic component, wherein the conductive structure is connected to the second electronic component and the circuit substrate and is connected to the second electronic component and the first electronic component;
three conductive adhesive materials, and one of the conductive adhesive materials is located between the first electronic component and the second electronic component, and another one of the conductive adhesive materials is located between the second electronic component and the conductive structure, and the other one of the conductive adhesive materials is located between the first electronic component and the conductive structure, wherein the first electronic component is electrically connected to the conductive structure through the one of the conductive adhesive materials, wherein the second electronic component is electrically connected to the first electronic component and the conductive structure separately through the other two of the conductive adhesive materials; and
a soldering material located between the circuit substrate and the first electronic component, wherein the circuit substrate is electrically connected to the first electronic component through the soldering material, and the melting point of at least two of the conductive adhesive materials is higher than the melting point of the soldering material.

10. The electronic package module of claim 9, wherein the melting point of the one of the conductive adhesive materials located between the first electronic component and the second electronic component is higher than the melting point of the soldering material, and the melting point of the other one of the conductive adhesive materials located between the first electronic component and the conductive structure is higher than the melting point of the soldering material.
